(19) United States
(12) Patent Application Publication
(10) Pub. No.: US 2026/0371546 A1
(43) Pub. Date: Nov. 19, 2026

(54) Layout Pattern of Static Random Access Memory and Method for Fabricating the Same

(71) Applicant: UNITED MICROELECTRONICS CORP, Hsin-Chu City (TW)

(72) Inventors: Chun-Hsien Huang, Tainan City (TW); Yu-Tse Kuo, Tainan City (TW); Shu-Ru Wang, Taichung City (TW); Chun-Yen Tseng, Tainan City (TW); Meng-Ping Chuang, Hsinchu City (TW); Li-Ping Huang, Miaoli County (TW)

(73) Assignee: UNITED MICROELECTRONICS CORP., Hsin-Chu City (TW)

(21) Appl. No.: 19/245,428

(22) Filed: Jun. 23, 2025

(30) Foreign Application Priority Data
May 16, 2025 (TW) 114118430

(51) Int. Cl. H10B 10/00; H10D 89/10

(52) U.S. Cl. CPC H10B 10/12; H10D 89/10

(57) ABSTRACT

The present invention provides a layout pattern of a static random access memory (SRAM), comprising an N-type strap area, wherein the N-type strap area includes a plurality of first M0 contact metals (M0CT1), a P-type strap area, adjacent to the N-type strap area, wherein the P-type strap area includes a plurality of second M0 contact metals (M0CT2), and an SRAM cell region, including a plurality of fin structures and a plurality of third M0 contact metals (M0CT3). A spacing between one of the first M0 contact metals closest to one of the third M0 contact metals is defined as a first spacing (D1), a spacing between one of the first M0 contact metals closest to one of the second M0 contact metals is defined as a second spacing (D2), and the first spacing (D1) is smaller than the second spacing (D2).

### BACKGROUND OF THE INVENTION

### 1. Field of the Invention

The present invention relates to a static random access memory (SRAM), and more particularly to a layout pattern of a static random access memory and a method for fabricating the same, which provide advantages such as reduced risk of short circuits and high yield.

### 2. Description of the Prior Art

In an embedded static random access memory (embedded SRAM), a logic circuit and a static random access memory connected to the logic circuit are included. The static random access memory itself is a volatile memory cell, meaning that the stored data is erased when the power supply to the static random access memory is lost. The static random access memory stores data by utilizing the conductive state of transistors within the memory cell. The design of the static random access memory is based on mutually coupled transistors, eliminating the issue of capacitor discharge and the need for constant recharging to prevent data loss, i.e., no memory refresh operation is required. This is distinct from dynamic random access memory (DRAM), another type of volatile memory, which stores data using the charged state of capacitors. The access speed of the static random access memory is very fast, making it suitable for applications such as cache memory in computer systems.

To reduce the size of transistors, semiconductor manufacturing technology has introduced three-dimensional structures, such as fin field effect transistors (FinFETs), which replace the source and drain in the substrate with protruding fin structures, thereby effectively reducing the area occupied by the device.

Memory devices utilize a large number of transistors to form memory cells. For example, the circuit of a memory cell in a static random access memory device may use six or more transistors to form a single memory cell. For instance, a memory cell may include two inverters. The inverters are composed of a P-type metal-oxide-semiconductor (PMOS) transistor and an N-type metal-oxide-semiconductor (NMOS) transistor. Additionally, other NMOS transistors are included to form a bilaterally symmetrical structure.

### SUMMARY OF THE INVENTION

The present invention provides a layout pattern of a static random access memory (SRAM), comprising an N-type strap area, wherein the N-type strap area includes a plurality of first M0 contact metals (M0CT1), the first M0 contact metals being disposed within the N-type strap area and connected to a power supply voltage (Vcc); a P-type strap area, adjacent to the N-type strap area, wherein the P-type strap area includes a plurality of second M0 contact metals (M0CT2), the second M0 contact metals being disposed within the P-type strap area and connected to a ground voltage (Vss); and an SRAM cell region, including a plurality of fin structures and a plurality of third M0 contact metals (M0CT3), wherein the SRAM cell region is adjacent to one side of the N-type strap area. A spacing between one of the first M0 contact metals closest to one of the third M0 contact metals is defined as a first spacing (D1), a spacing between one of the first M0 contact metals closest to one of the second M0 contact metals is defined as a second spacing (D2), and the first spacing (D1) is smaller than the second spacing (D2).

The present invention further provides a method for fabricating a static random access memory (SRAM), comprising forming an N-type strap area, wherein the N-type strap area includes a plurality of first M0 contact metals (M0CT1), the first M0 contact metals being disposed within the N-type strap area and connected to a power supply voltage (Vcc); forming a P-type strap area, adjacent to the N-type strap area, wherein the P-type strap area includes a plurality of second M0 contact metals (M0CT2), the second M0 contact metals being disposed within the P-type strap area and connected to a ground voltage (Vss); and forming an SRAM cell region, including a plurality of fin structures and a plurality of third M0 contact metals (M0CT3), wherein the SRAM cell region is adjacent to one side of the N-type strap area. A spacing between one of the first M0 contact metals closest to one of the third M0 contact metals is defined as a first spacing (D1), a spacing between one of the first M0 contact metals closest to one of the second M0 contact metals is defined as a second spacing (D2), and the first spacing (D1) is smaller than the second spacing (D2).

In summary, the present invention provides a layout pattern of a static random access memory and a method for fabricating the same. The feature of the present invention lies in designing and arranging the positions of the N-type strap area and the P-type strap area, and adjusting the positions of the respective M0 contact metals within the N-type strap area and the P-type strap area, intentionally preventing the formation of M0 contact metals at the boundary between the N-type strap area and the P-type strap area, and defining a blank region. The layout pattern of the present invention can solve the issue of mutual interference due to excessively close proximity of components in some embodiments. Therefore, the advantages of the present invention include: 1. Reduced risk of short circuits, 2. Improved yield, 3. Reduced layout area, 4. Optimized layout, and 5. High process compatibility.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

To facilitate understanding of the following description, the drawings and their detailed descriptions may be referenced simultaneously while reading the present invention. Through the specific embodiments described herein and with reference to the corresponding drawings, the specific embodiments of the present invention are explained in detail and used to illustrate the operational principles of the specific embodiments of the present invention. Additionally, for the sake of clarity, the features in the drawings may not be drawn to actual scale, and thus the dimensions of some features in certain drawings may be intentionally enlarged or reduced.

FIG. 1 is a circuit diagram of a six-transistor static random access memory (6T-SRAM) memory cell in a static random access memory according to a first embodiment of the present invention.

FIG. 2 is a layout diagram of a static random access memory according to the present invention.

FIG. 3 is a schematic diagram of a semiconductor layout pattern according to an embodiment of the present invention.

FIG. 4 is a partial enlarged view of the N-type strap area NS and the P-type strap area PS in FIG. 3.

FIG. 5 is a schematic diagram of a semiconductor layout pattern according to another embodiment of the present invention, emphasizing the relationships between various regions.

FIG. 6 is a partial enlarged view of the semiconductor layout pattern in the embodiment of FIG. 5.

### DETAILED DESCRIPTION

To enable those skilled in the art to further understand the present invention, preferred embodiments of the present invention are specifically listed below, and in conjunction with the accompanying drawings, the structure and intended effects of the present invention are described in detail.

For convenience of explanation, the drawings of the present invention are merely schematic to facilitate understanding of the present invention, and their detailed proportions may be adjusted according to design requirements. The relative positional relationships of components in the drawings described herein should be understood by those skilled in the art as referring to the relative positions of objects, and thus may be flipped to present the same components, all of which should fall within the scope of the present disclosure, as stated herein.

Although the present invention uses terms such as first, second, third, etc., to describe elements, components, regions, layers, and/or sections, it should be understood that these elements, components, regions, layers, and/or sections should not be limited by these terms. These terms are only used to distinguish one element, component, region, layer, and/or section from another element, component, region, layer, and/or section, and do not imply any prior ordinality for the element, nor do they indicate the arrangement order of one element relative to another or the order in the manufacturing process. Therefore, without departing from the scope of the specific embodiments of the present invention, a first element, component, region, layer, or section discussed below may also be referred to as a second element, component, region, layer, or section.

The terms “approximately” or “substantially” as used in the present invention generally mean within 20% of a given value or range, for example, within 10%, or within 5%, or within 3%, or within 2%, or within 1%, or within 0.5%. It should be noted that the quantities provided in the specification are approximate quantities, meaning that the terms “approximately” or “substantially” may be implied even if not explicitly stated.

The terms “coupled,” “coupling,” or “electrically connected” as used in the present invention include any direct or indirect electrical connection means. For example, if it is described herein that a first component is coupled to a second component, it means that the first component may be directly electrically connected to the second component or indirectly electrically connected to the second component through other devices or connection means.

Although the present invention is described below through specific embodiments, the principles of the present invention may also be applied to other embodiments. Furthermore, to avoid obscuring the spirit of the present invention, certain details may be omitted, and the omitted details fall within the knowledge scope of those with ordinary skill in the relevant technical field.

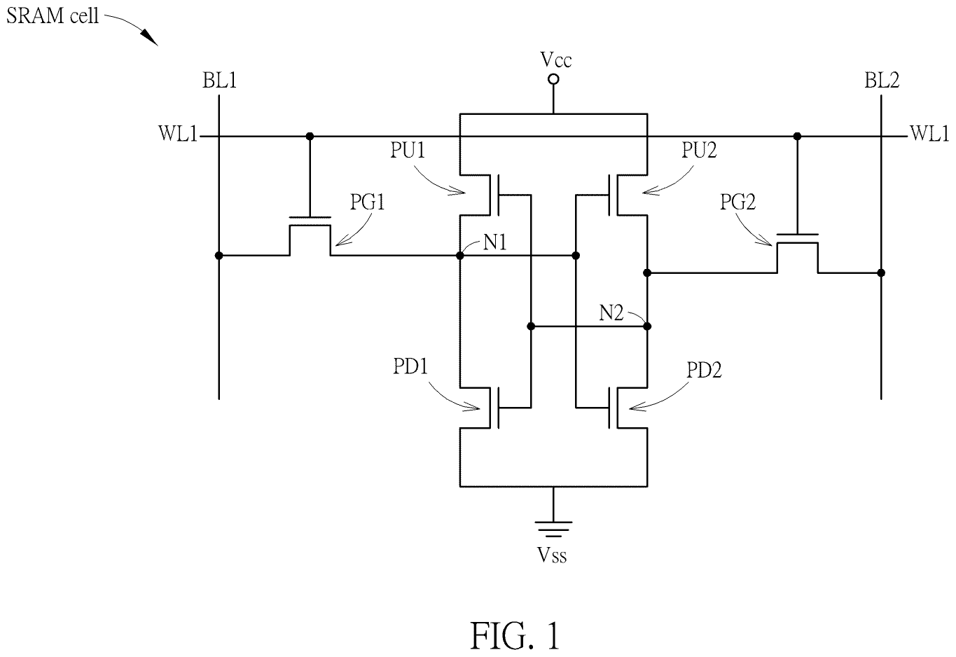

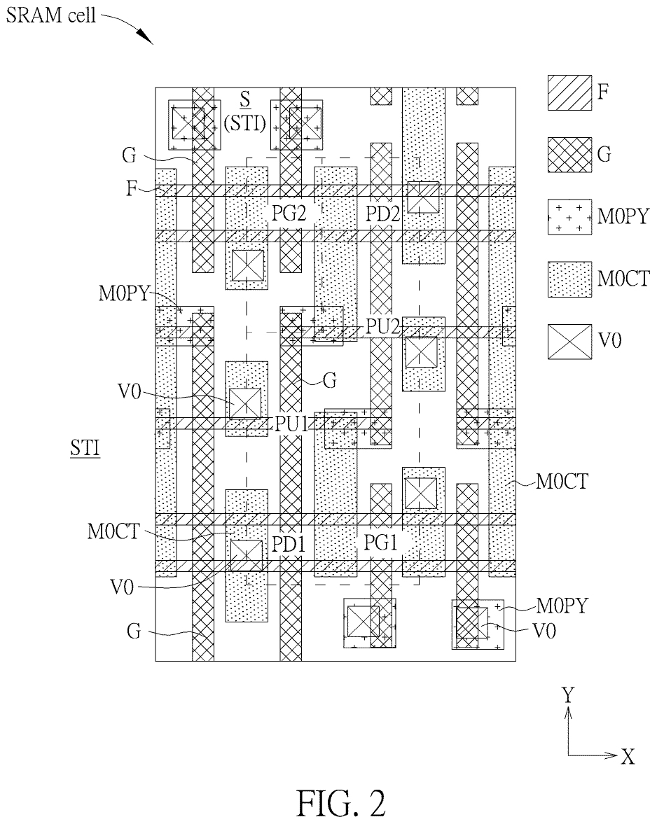

Please refer to FIG. 1 and FIG. 2. FIG. 1 is a circuit diagram of a six-transistor static random access memory (6T-SRAM) memory cell in a static random access memory according to a first embodiment of the present invention. FIG. 2 is a layout diagram of a static random access memory cell according to the present invention.

In this embodiment, at least one six-transistor static random access memory (6T-SRAM) memory cell (SRAM cell) is included. Each 6T-SRAM memory cell (SRAM cell) preferably comprises a first pull-up transistor (PU1), a second pull-up transistor (PU2), a first pull-down transistor (PD1), a second pull-down transistor (PD2), a first pass gate transistor (PG1), and a second pass gate transistor (PG2), forming a flip-flop. The first pull-up transistor (PU1), the second pull-up transistor (PU2), the first pull-down transistor (PD1), and the second pull-down transistor (PD2) form a latch circuit, enabling data to be latched at a storage node (N1) or a storage node (N2). Additionally, the first pull-up transistor (PU1) and the second pull-up transistor (PU2) serve as active loads and may be replaced with resistors as pull-up transistors, in which case it becomes a four-transistor static random access memory (4T-SRAM). In this embodiment, a source region of each of the first pull-up transistor (PU1) and the second pull-up transistor (PU2) is electrically connected to a voltage source (Vcc), and a source region of each of the first pull-down transistor (PD1) and the second pull-down transistor (PD2) is electrically connected to a voltage source (Vss).

In an embodiment, the first pull-up transistor (PU1) and the second pull-up transistor (PU2) of the 6T-SRAM memory cell (SRAM cell) are composed of P-type metal oxide semiconductor (PMOS) transistors, while the first pull-down transistor (PD1), the second pull-down transistor (PD2), the first pass gate transistor (PG1), and the second pass gate transistor (PG2) are composed of N-type metal oxide semiconductor (NMOS) transistors, but not limited thereto. The first pull-up transistor (PU1) and the first pull-down transistor (PD1) together form an inverter, and a series circuit formed by these two has its endpoints coupled to the voltage source (Vcc) and the voltage source (Vss), respectively. Similarly, the second pull-up transistor (PU2) and the second pull-down transistor (PD2) form another inverter, and a series circuit formed by these two has its endpoints coupled to the voltage source (Vcc) and the voltage source (Vss), respectively. The two inverters are mutually coupled to store data.

Furthermore, at the storage node (N1), a gate of the second pull-down transistor (PD2), a gate of the second pull-up transistor (PU2), a drain of the first pull-down transistor (PD1), a drain of the first pull-up transistor (PU1), and a drain of the first pass gate transistor (PG1) are electrically connected, respectively. Similarly, at the storage node (N2), a gate of the first pull-down transistor (PD1), a gate of the first pull-up transistor (PU1), a drain of the second pull-down transistor (PD2), a drain of the second pull-up transistor (PU2), and a drain of the second pass gate transistor (PG2) are electrically connected, respectively. The gates of the first pass gate transistor (PG1) and the second pass gate transistor (PG2) are coupled to a word line (WL), respectively, while a source of the first pass gate transistor (PG1) and a source of the second pass gate transistor (PG2) are coupled to a corresponding first bit line (BL1) and a second bit line (BL2), respectively.

FIG. 2 is a layout diagram of a static random access memory cell according to the present invention. In this embodiment, as shown in FIG. 2, the 6T-SRAM memory cell (SRAM cell) is disposed on a substrate (S), such as a silicon substrate or a silicon-on-insulator (SOI) substrate. The substrate (S) may be a planar structure or provided with a plurality of fin structures (F), and a plurality of gate structures (G) are located on the substrate (S). In other embodiments of the present invention, the invention may also be applied to planar SRAMs, meaning that it is not necessary to form fin structures on the substrate, but rather to form doped regions within the substrate, which also falls within the scope of the present invention.

For the design of fin field effect transistors, the fin structures (F) used to form the source and drain extend in a horizontal direction (Y-direction). The gate structures (G) extending in a vertical direction intersect the fin structures (F). The gate structures (G) are generally made of polysilicon, for example. Since the plurality of gate structures (G) extend along the same vertical line, they may collectively be referred to as a gate line. Other detailed structures are understood by those skilled in the art, and their description is omitted here.

Additionally, the layout diagram of FIG. 2 includes a plurality of metal layers. A metal layer connecting the gates of the transistors is defined as M0PY, while a metal layer connecting the source/drain of the transistors is defined as M0CT. Since both M0CT and M0PY are formed in the zeroth metal layer (0th metal), M0CT and M0PY are both referred to as M0 contact metals hereinafter. In this embodiment, the M0 contact metal (M0PY) and the M0 contact metal (M0CT) are formed between gate lines and are appropriately connected to the transistors to achieve the circuit structure of the memory cell. In FIG. 2, the M0 contact metal (M0PY) and the M0 contact metal (M0CT) are represented with different hatch patterns. In practice, the difference between the M0 contact metal (M0PY) and the M0 contact metal (M0CT) lies in the connected components (the M0 contact metal (M0PY) is connected to the gate, while the M0 contact metal (M0CT) is not connected to the gate). Both are actually metal layers and may comprise the same material, but not limited thereto. FIG. 2 also includes a plurality of contact vias (V0), wherein the contact vias (V0) are used to connect the M0 contact metal (M0PY) and the M0 contact metal (M0CT) to other conductive layers formed subsequently (e.g., M1, V1, M2, etc., commonly used in semiconductor processes).

In the layout pattern of the present invention, a three-dimensional SRAM is taken as an example (i.e., forming fin structures (F) instead of planar doped regions). As shown in FIG. 2, in addition to the positions where the fin structures (F), the gate structures (G), the M0 contact metal (M0PY), the M0 contact metal (M0CT), and the contact vias (V0) are formed on the substrate (S), the rest of the substrate (S) is covered with an insulating layer, such as a shallow trench isolation (STI) structure, to isolate electronic components (e.g., transistors) and prevent short circuits. Furthermore, each gate structure (G) spans over a portion of the fin structures (F) to form transistors (e.g., the first pull-up transistor (PU1), the second pull-up transistor (PU2), the first pull-down transistor (PD1), the second pull-down transistor (PD2), the first pass gate transistor (PG1), and the second pass gate transistor (PG2)). For clarity, the positions of the aforementioned transistors are directly marked in FIG. 2, particularly at the intersections of the gate structures (G) and the fin structures (F).

The layout diagram of the static random access memory cell described in FIG. 2 refers to the layout pattern of a single 6T-SRAM on the substrate (S). However, in actual manufacturing processes, electronic products may include multiple 6T-SRAMs, so the overall semiconductor layout diagram may also include multiple 6T-SRAMs. That is, the substrate (S) includes a plurality of arranged 6T-SRAM cells, wherein adjacent 6T-SRAM layout patterns may be mirrored relative to each other to share certain components. In the following paragraphs, since the focus is on the N-type pickup region and the P-type pickup region adjacent to the 6T-SRAM cell, the layout patterns of some 6T-SRAM cells may be omitted. However, those skilled in the art should understand that the layout patterns of these 6T-SRAM cells correspond to the layout pattern shown in FIG. 2 (or a mirrored version of the layout pattern in FIG. 2).

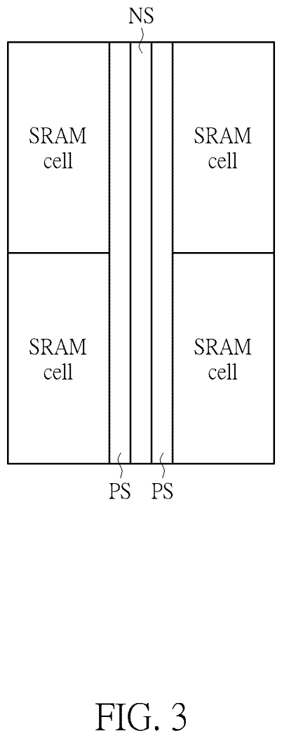

FIG. 3 is a schematic diagram of a semiconductor layout pattern according to an embodiment of the present invention. As shown in FIG. 3, generally, in the P-type transistors and N-type transistors included in each 6T-SRAM memory cell (SRAM cell), the substrate of the P-type transistors is provided by an N-type well region (N-type diffusion region), while the substrate of the N-type transistors is provided by a P-type well region (P-type diffusion region). In the layout, to allow the voltage source to be transmitted to each P-type transistor or N-type transistor, an N-type strap area (NS) is planned to transmit the voltage source (Vcc) to the P-type transistors (e.g., the first pull-up transistor (PU1) and the second pull-up transistor (PU2)), and a P-type strap area (PS) is planned to transmit the voltage source (Vss) to the N-type transistors (e.g., the first pull-down transistor (PD1), the second pull-down transistor (PD2), the first pass gate transistor (PG1), and the second pass gate transistor (PG2)).

For example, in FIG. 3, an N-type strap area (NS) extending along a longitudinal direction (Y-direction) and a P-type strap area (PS) also extending along the longitudinal direction (Y-direction) are included. The N-type strap area (NS) provides the voltage (Vcc) for the P-type transistors, and the P-type strap area (PS) provides the voltage (Vss) for the N-type transistors. More specifically, each SRAM cell shown in FIG. 3 represents a 6T-SRAM memory cell (refer to FIG. 2). Generally, when allocating multiple transistors of the 6T-SRAM memory cell, the PMOS transistors are planned in a single row (where a “row” refers to a direction along the X-direction or horizontal direction), while the NMOS transistors are arranged in the rows above and below the PMOS row. Then, the PMOS transistors are collectively connected to the N-type strap area (NS) through subsequently formed conductive lines (e.g., along the X-direction), and the NMOS transistors are collectively connected to the P-type strap area (PS) through subsequently formed conductive lines (e.g., along the X-direction).

In this embodiment, to provide the layout pattern with better symmetry, the N-type strap area (NS) is disposed in the layout pattern, and two P-type strap areas (PS) are disposed on the left and right sides of the N-type strap area (NS). Other 6T-SRAM memory cells (SRAM cells) are located adjacent to the N-type strap area (NS).

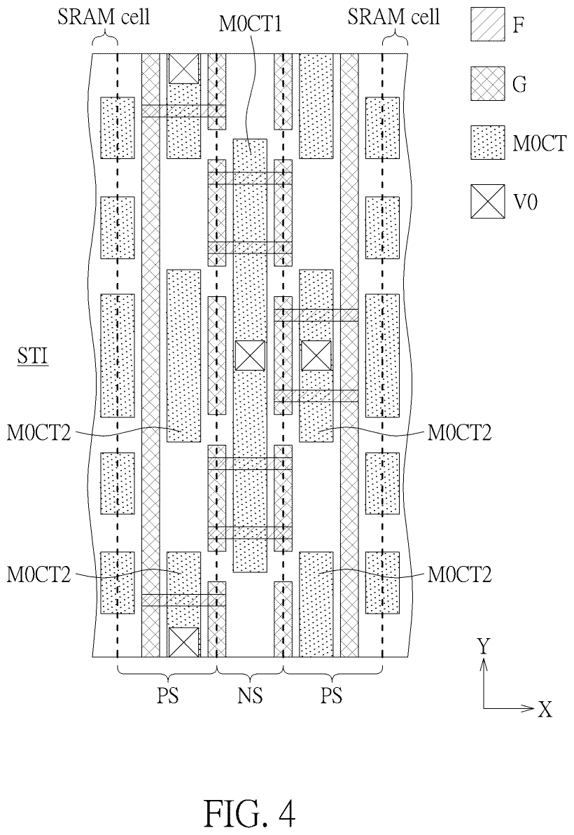

Based on the observations of the applicant, although the layout pattern shown in FIG. 3 has a high degree of symmetry, the applicant has also identified some potential issues in this layout pattern. Please refer to FIG. 4, which is a partial enlarged view of the N-type strap area (NS) and the P-type strap area (PS) in FIG. 3. As shown in FIG. 4, a plurality of M0 contact metals (M0CT1) within the N-type strap area (NS) are defined first, wherein the M0 contact metals (M0CT1) are used to connect to the voltage source (Vcc), and a plurality of M0 contact metals (M0CT2) within the P-type strap area (PS) are defined, wherein the M0 contact metals (M0CT2) are used to connect to the voltage source (Vss). As shown in FIG. 4, the M0 contact metals (M0CT1) are located in the middle, while the M0 contact metals (M0CT2) are alternately arranged on the left and right sides of the M0 contact metals (M0CT1). Based on the applicant's observations, it was found that when arranged in this manner, the distance between the M0 contact metals (M0CT1) and the M0 contact metals (M0CT2) is relatively small, which may easily cause mutual interference between the two components. For example, if the etching process for cutting the fin structures (F) is incomplete, the unremoved portions of the fin structures may affect adjacent components, causing electrical errors.

In short, in the layout pattern described above, the N-type strap area (NS) is located in the middle of the layout pattern, and the P-type strap areas (PS) are located on the left and right sides of the N-type strap area (NS). Although this provides high symmetry, it also results in a relatively small distance between the P-type strap areas (PS) and the N-type strap area (NS), which may lead to corresponding disadvantages, such as the fin structures affecting adjacent components. In the following embodiments, an improved layout pattern is proposed, which has the advantage of improving component yield compared to the layout patterns shown in FIG. 3 and FIG. 4.

The following description will address different embodiments of the present invention. To simplify the explanation, the description will focus on the differences between the embodiments, and repeated descriptions of identical aspects will not be provided. Furthermore, identical elements in the embodiments of the present invention are denoted with the same reference numerals to facilitate cross-referencing between the embodiments.

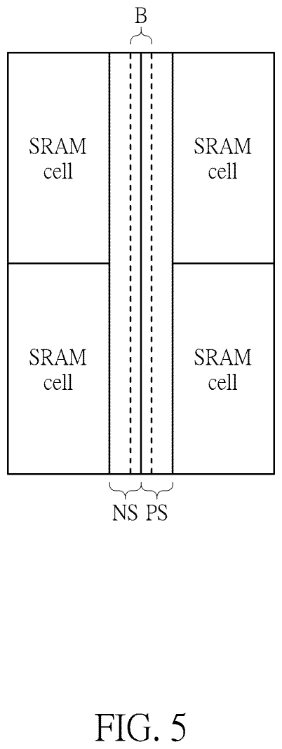

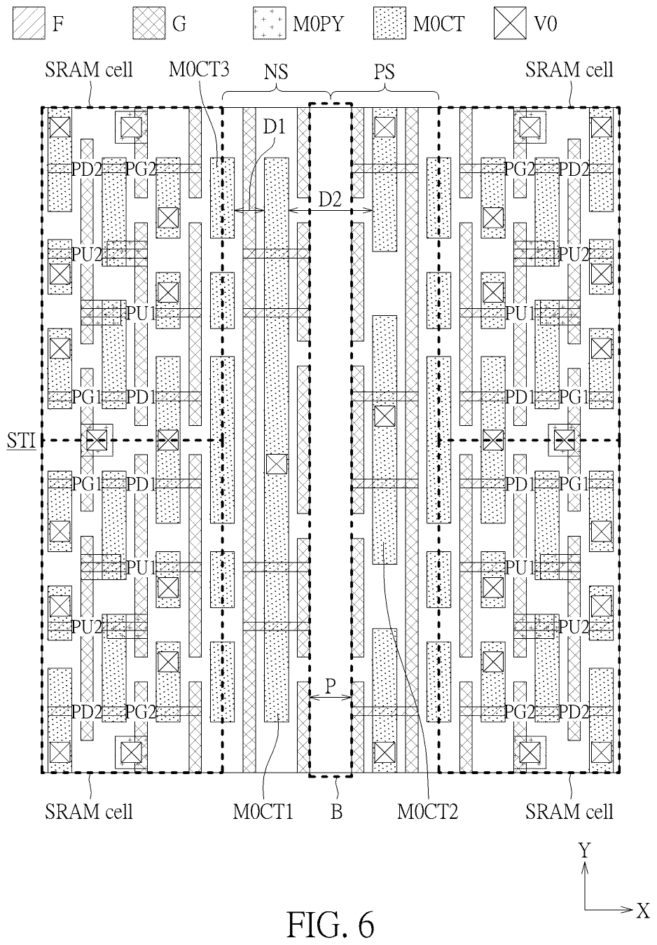

Please refer to FIG. 5 and FIG. 6. FIG. 5 is a schematic diagram of a semiconductor layout pattern according to another embodiment of the present invention, emphasizing the relationships between various regions. FIG. 6 is a partial enlarged view of the semiconductor layout pattern in the embodiment of FIG. 5. As shown in FIG. 5, the difference between this embodiment and the previous embodiment lies in that this embodiment adjusts the positions of the N-type strap area (NS) and the P-type strap area (PS). Compared to the previous embodiment (FIG. 3 and FIG. 4), where one N-type strap area (NS) is located between two P-type strap areas (PS), in this embodiment, only one N-type strap area (NS) and one P-type strap area (PS) are adjacently disposed between a plurality of 6T-SRAM memory cells (SRAM cells). The N-type strap area (NS) is located between a portion of the SRAM cells and the P-type strap area (PS), and the P-type strap area (PS) is located between another portion of the SRAM cells and the N-type strap area (NS). Additionally, a blank region (B) is defined between the N-type strap area (NS) and the P-type strap area (PS), wherein the blank region (B) does not include any M0 contact metal (M0CT) or M0 contact metal (M0PY). The purpose of defining the blank region (B) is to prevent the formation of the M0 contact metal (M0CT) or the M0 contact metal (M0PY) at the boundary between the N-type strap area (NS) and the P-type strap area (PS). Therefore, even if the fin structures (F) in the N-type strap area (NS) or the P-type strap area (PS) extend into the adjacent region due to their longer length, the absence of the M0 contact metal (M0CT) or the M0 contact metal (M0PY) in the blank region (B) makes it unlikely for the fin structures (F) to affect adjacent components.

Thus, compared to the previous embodiment, this embodiment adjusts the distribution positions of the N-type strap area (NS) and the P-type strap area (PS) and defines the blank region (B) between the N-type strap area (NS) and the P-type strap area (PS), effectively reducing the likelihood of mutual interference due to the close proximity of components, thereby improving the yield of the semiconductor structure.

It is also worth noting that this embodiment includes several layout features. Please refer to FIG. 6. First, a plurality of M0 contact metals (M0CT) are located within the N-type strap area (NS), one of which is defined as M0CT1, and a plurality of M0 contact metals (M0CT) are also located within the P-type strap area (PS), one of which is defined as M0CT2. A structural feature of this embodiment is that a length of the M0 contact metal (M0CT1) in a longitudinal direction (Y-direction) is greater than a length of the M0 contact metal (M0CT2) in the longitudinal direction (Y-direction). This design helps reduce the number of subsequent connecting conductive lines, allowing the voltage source (Vcc) and the voltage source (Vss) to be connected to the corresponding components in a more relaxed layout.

Please continue to refer to FIG. 6. Another feature from the layout perspective is that a spacing between two adjacent gate structures (G) is defined as P, i.e., a spacing between two adjacent gate structures (G) in an X-direction is p. In the layout pattern of the present invention, a width of the N-type strap area (NS) is less than or equal to 2P, and a width of the P-type strap area (PS) is also less than or equal to 2P. Additionally, a width of the blank region (B) is approximately equal to P. If the above conditions are met, the area of each region can be controlled within a smaller range, which is beneficial for device miniaturization and dense arrangement. At the same time, due to the presence of the blank region (B), the likelihood of mutual interference between adjacent components can be reduced. More specifically, as shown in FIG. 6, the N-type strap area (NS) and the P-type strap area (PS) are adjacent, but except for the blank region (B), the remaining regions, including the SRAM cell region, the N-type strap area (NS), and the P-type strap area (PS), include the M0 contact metals (M0CT). The blank region (B) is defined at a boundary between the N-type strap area (NS) and the P-type strap area (PS) and does not include any M0 contact metal (M0CT). In other words, in the layout pattern of this embodiment, the M0 contact metals (M0CT) are intentionally not formed at the boundary between the N-type strap area (NS) and the P-type strap area (PS), thereby avoiding the opportunity for adjacent components to interfere with each other.

A third feature of the layout pattern of this embodiment is that some fin structures (F) are located within the N-type strap area (NS) and the P-type strap area (PS). However, the fin structures (F) within the N-type strap area (NS) do not directly contact the fin structures (F) located in an adjacent SRAM cell region, and similarly, the fin structures (F) within the P-type strap area (PS) do not directly contact the fin structures (F) located in an adjacent SRAM cell region. In other words, after forming the fin structures and performing a fin structure segmentation step, the fin structures (F) at a boundary between the N-type strap area (NS) and the SRAM cell region are cut off, and similarly, the fin structures (F) at a boundary between the P-type strap area (PS) and the SRAM cell region are also cut off. It is also worth noting that the blank region (B) does not include any fin structures (F). More specifically, the blank region (B) is a region with a width of p (approximately equal to a spacing between two adjacent gate structures (G) in the X-direction) that includes only the substrate (S) and the shallow trench isolation structure (STI), and does not include, for example, the gate structures (G), the fin structures (F), or the M0 contact metals (M0CT, M0PY). The blank region (B) extends along the Y-direction.

In summary, based on the above description and drawings, the present invention provides a static random access memory (SRAM) structure, comprising an N-type strap area (NS), wherein the N-type strap area (NS) includes a plurality of first M0 contact metals (M0CT1), the first M0 contact metals (M0CT1) being disposed within the N-type strap area (NS) and connected to a power supply voltage (Vcc); a P-type strap area (PS), adjacent to the N-type strap area (NS), wherein the P-type strap area (PS) includes a plurality of second M0 contact metals (M0CT2), the second M0 contact metals (M0CT2) being disposed within the P-type strap area (PS) and connected to a ground voltage (Vss); and an SRAM cell region (SRAM cell), including a plurality of fin structures (F) and a plurality of third M0 contact metals (M0CT3, as defined in FIG. 6 as a metal layer located within the SRAM cell), wherein the SRAM cell region (SRAM cell) is adjacent to one side of the N-type strap area (NS) (e.g., in FIG. 6, the SRAM cell is located on a left side of the N-type strap area (NS)). A spacing between one of the first M0 contact metals (M0CT1) closest to one of the third M0 contact metals (M0CT3) is defined as a first spacing (D1, as shown in FIG. 6), a spacing between one of the first M0 contact metals (M0CT1) closest to one of the second M0 contact metals (M0CT2) is defined as a second spacing (D2, as defined in FIG. 6), and the first spacing (D1) is smaller than the second spacing (D2).

In some embodiments of the present invention, a region between the N-type strap area (NS) and the P-type strap area (PS) is defined as a blank region (B), the blank region (B) does not include any M0 contact metals (including the first M0 contact metals (M0CT1), the second M0 contact metals (M0CT2), or the third M0 contact metals (M0CT3)), and the second spacing (D2) is located within the blank region (B) (or overlaps with the blank region (B)).

In some embodiments of the present invention, a length of the first M0 contact metals (M0CT1) in a longitudinal direction (Y-direction) is greater than a length of the second M0 contact metals (M0CT2) in the longitudinal direction.

In some embodiments of the present invention, another side of the P-type strap area (PS) is directly adjacent to another SRAM cell region (as shown in FIG. 6, another SRAM cell is on a right side of the P-type strap area (PS)).

In some embodiments of the present invention, the first M0 contact metals (M0CT1) and the second M0 contact metals (M0CT2) are respectively disposed within the N-type strap area and the P-type strap area along a longitudinal direction.

In some embodiments of the present invention, the SRAM cell region includes a plurality of third M0 contact metals (M0CT3), and a shortest spacing between any two adjacent third M0 contact metals (M0CT3) in a horizontal direction is defined as D3, wherein D3 is equal to D1.

In some embodiments of the present invention, the first M0 contact metals (M0CT1) are used to connect an N-type diffusion region and a P-type metal oxide semiconductor transistor, and the second M0 contact metals (M0CT2) are used to connect a P-type diffusion region and an N-type metal oxide semiconductor transistor.

In some embodiments of the present invention, a plurality of gate structures (G) span over the fin structures (F) and form a plurality of fin field effect transistors (FinFETs), wherein an arrangement direction of the gate structures (G) is the same as an arrangement direction of the third M0 contact metals (M0CT3), and the gate structures (G) are located between two adjacent third M0 contact metals (M0CT3).

In some embodiments of the present invention, a width of the blank region (B) is equal to a distance p between two adjacent gate structures (G) in a horizontal direction, and the blank region (B) does not include the first M0 contact metals (M0CT1), the second M0 contact metals (M0CT2), or the third M0 contact metals (M0CT3).

In some embodiments of the present invention, a dummy region is not included between the N-type strap area (NS) and the SRAM cell region.

The present invention further provides a method for fabricating a static random access memory (SRAM), comprising forming an N-type strap area (NS), wherein the N-type strap area (NS) includes a plurality of first M0 contact metals (M0CT1), the first M0 contact metals (M0CT1) being disposed within the N-type strap area (NS) and connected to a power supply voltage (Vcc); forming a P-type strap area (PS), adjacent to the N-type strap area (NS), wherein the P-type strap area (PS) includes a plurality of second M0 contact metals (M0CT2), the second M0 contact metals (M0CT2) being disposed within the P-type strap area (PS) and connected to a ground voltage (Vss); and forming an SRAM cell region (SRAM cell), including a plurality of fin structures (F) and a plurality of third M0 contact metals (M0CT3, as defined in FIG. 6 as a metal layer located within the SRAM cell), wherein the SRAM cell region (SRAM cell) is adjacent to one side of the N-type strap area (NS) (e.g., in FIG. 6, the SRAM cell is located on a left side of the N-type strap area (NS)). A spacing between one of the first M0 contact metals (M0CT1) closest to one of the third M0 contact metals (M0CT3) is defined as a first spacing (D1, as shown in FIG. 6), a spacing between one of the first M0 contact metals (M0CT1) closest to one of the second M0 contact metals (M0CT2) is defined as a second spacing (D2, as defined in FIG. 6), and the first spacing (D1) is smaller than the second spacing (D2).

In summary, the present invention provides a layout pattern of a static random access memory and a method for fabricating the same. The feature of the present invention lies in designing and arranging the positions of the N-type strap area and the P-type strap area, and adjusting the positions of the respective M0 contact metals within the N-type strap area and the P-type strap area, intentionally preventing the formation of M0 contact metals at the boundary between the N-type strap area and the P-type strap area, and defining a blank region. The layout pattern of the present invention can solve the issue of mutual interference due to excessively close proximity of components in some embodiments. Therefore, the advantages of the present invention include: 1. Reduced risk of short circuits, 2. Improved yield, 3. Reduced layout area, 4. Optimized layout, and 5. High process compatibility.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A layout pattern of a static random access memory (SRAM), comprising:
an N-type strap area, wherein the N-type strap area includes a plurality of first M0 contact metals (M0CT1), the first M0 contact metals being disposed within the N-type strap area and connected to a power supply voltage (Vcc);
a P-type strap area, adjacent to the N-type strap area, wherein the P-type strap area includes a plurality of second M0 contact metals (M0CT2), the second M0 contact metals being disposed within the P-type strap area and connected to a ground voltage (Vss);
an SRAM cell region, including a plurality of fin structures and a plurality of third M0 contact metals (M0CT3), wherein the SRAM cell region is adjacent to one side of the N-type strap area;
wherein a spacing between one of the first M0 contact metals closest to one of the third M0 contact metals is defined as a first spacing (D1), a spacing between one of the first M0 contact metals closest to one of the second M0 contact metals is defined as a second spacing (D2), and the first spacing (D1) is smaller than the second spacing (D2).

2. The layout pattern of the static random access memory according to claim 1, wherein a region between the N-type strap area and the P-type strap area is defined as a blank region, the blank region does not include any M0 contact metals, and the second spacing (D2) is located within the blank region.

3. The layout pattern of the static random access memory according to claim 1, wherein a length of the first M0 contact metals in a longitudinal direction is greater than a length of the second M0 contact metals in the longitudinal direction.

4. The layout pattern of the static random access memory according to claim 1, wherein another side of the P-type strap area is directly adjacent to another SRAM cell region.

5. The layout pattern of the static random access memory according to claim 1, wherein the first M0 contact metals (M0CT1) and the second M0 contact metals (M0CT2) are respectively disposed within the N-type strap area and the P-type strap area along a longitudinal direction.

6. The layout pattern of the static random access memory according to claim 1, wherein the SRAM cell region includes a plurality of third M0 contact metals (M0CT3), and a shortest spacing between any two adjacent third M0 contact metals (M0CT3) in a horizontal direction is defined as D3, wherein D3 is equal to D1.

7. The layout pattern of the static random access memory according to claim 1, wherein the first M0 contact metals are used to connect an N-type diffusion region and a P-type metal oxide semiconductor transistor, and the second M0 contact metals are used to connect a P-type diffusion region and an N-type metal oxide semiconductor transistor.

8. The layout pattern of the static random access memory according to claim 1, further comprising a plurality of gate structures spanning over the fin structures and forming a plurality of fin field effect transistors, wherein an arrangement direction of the gate structures is the same as an arrangement direction of the third M0 contact metals (M0CT3), and the gate structures are located between two adjacent third M0 contact metals (M0CT3).

9. The layout pattern of the static random access memory according to claim 8, wherein a width of the blank region is equal to a distance between two adjacent gate structures in a horizontal direction, and the blank region does not include the first M0 contact metals (M0CT1), the second M0 contact metals (M0CT2), or the third M0 contact metals (M0CT3).

10. The layout pattern of the static random access memory according to claim 1, wherein a dummy region is not included between the N-type strap area and the SRAM cell region.

11. A method for fabricating a static random access memory (SRAM), comprising:
forming an N-type strap area, wherein the N-type strap area includes a plurality of first M0 contact metals (M0CT1), the first M0 contact metals being disposed within the N-type strap area and connected to a power supply voltage (Vcc);
forming a P-type strap area, adjacent to the N-type strap area, wherein the P-type strap area includes a plurality of second M0 contact metals (M0CT2), the second M0 contact metals being disposed within the P-type strap area and connected to a ground voltage (Vss);
forming an SRAM cell region, including a plurality of fin structures and a plurality of third M0 contact metals (M0CT3), wherein the SRAM cell region is adjacent to one side of the N-type strap area;
wherein a spacing between one of the first M0 contact metals closest to one of the third M0 contact metals is defined as a first spacing (D1), a spacing between one of the first M0 contact metals closest to one of the second M0 contact metals is defined as a second spacing (D2), and the first spacing (D1) is smaller than the second spacing (D2).

12. The method for fabricating the static random access memory structure according to claim 11, wherein a region between the N-type strap area and the P-type strap area is defined as a blank region, the blank region does not include any M0 contact metals, and the second spacing (D2) is located within the blank region.

13. The method for fabricating the static random access memory structure according to claim 11, wherein a length of the first M0 contact metals in a longitudinal direction is greater than a length of the second M0 contact metals in the longitudinal direction.

14. The method for fabricating the static random access memory structure according to claim 11, wherein another side of the P-type strap area is directly adjacent to another SRAM cell region.

15. The method for fabricating the static random access memory structure according to claim 11, wherein the first M0 contact metals (M0CT1) and the second M0 contact metals (M0CT2) are respectively disposed within the N-type strap area and the P-type strap area along a longitudinal direction.

16. The method for fabricating the static random access memory structure according to claim 11, wherein the SRAM cell region includes a plurality of third M0 contact metals (M0CT3), and a shortest spacing between any two adjacent third M0 contact metals (M0CT3) in a horizontal direction is defined as D3, wherein D3 is equal to D1.

17. The method for fabricating the static random access memory structure according to claim 11, wherein the first M0 contact metals are used to connect an N-type diffusion region and a P-type metal oxide semiconductor transistor, and the second M0 contact metals are used to connect a P-type diffusion region and an N-type metal oxide semiconductor transistor.

18. The method for fabricating the static random access memory structure according to claim 11, further comprising forming a plurality of gate structures spanning over the fin structures and forming a plurality of fin field effect transistors, wherein an arrangement direction of the gate structures is the same as an arrangement direction of the third M0 contact metals (M0CT3), and the gate structures are located between two adjacent third M0 contact metals (M0CT3).

19. The method for fabricating the static random access memory structure according to claim 18, wherein a width of the blank region is equal to a distance between two adjacent gate structures in a horizontal direction, and the blank region does not include the first M0 contact metals (M0CT1), the second M0 contact metals (M0CT2), or the third M0 contact metals (M0CT3).

20. The method for fabricating the static random access memory structure according to claim 11, wherein a dummy region is not included between the N-type strap area and the SRAM cell region.
